(19) United States
(12) Patent Application Publication
(10) Pub. No.: US 2011/0111563 A1
(43) Pub. Date: May 12, 2011

(54) ADHESIVE TAPE FOR RESIN-ENCAPSULATING AND METHOD OF MANUFACTURE OF RESIN-ENCAPSULATED SEMICONDUCTOR DEVICE

(75) Inventors: Yuichiro YANAGI, Ibaraki-shi (JP); Hiroyuki Kondo, Ibaraki-shi (JP); Shinji Hoshino, Ibraki-shi (JP); Daisuke Shimokawa, Ibaraki-shi (JP)

(73) Assignee: NITTO DENKO CORPORATION, Osaka (JP)

(21) Appl. No.: 12/944,459

(22) Filed: Nov. 11, 2010

(30) Foreign Application Priority Data
Nov. 12, 2009 (JP) 2009-258633

(51) Int. Cl. H01L 21/56; C09J 7/02; B32B 33/00

(52) U.S. Cl. 438/118; 428/220; 428/41.8; 257/E21.502

(57) ABSTRACT

An adhesive tape for resin-encapsulating used in a method of manufacture of a resin-encapsulated semiconductor device has a base material layer and an adhesive agent layer laminated on the base material layer, a total film thickness of the base material layer and the adhesive agent layer of 25 to 40 μm. According to the adhesive tape for resin encapsulating of the present invention, resin leakage can be efficiently prevented during the resin encapsulating operation.

### BACKGROUND OF THE INVENTION

1. Field of the Invention

The present invention relates to an adhesive tape for resin-encapsulating and a method of manufacture of a resin-encapsulated semiconductor device.

2. Background Information

In recent years, CSP (chip size/scale package) techniques are attracting attention as an LSI mounting technology. Among these techniques, the downsizing and high-integration characteristics of a package with a lead terminal incorporated into an inner portion of the package which are typically in a QFN (quad flat non-leaded package) configuration have attracted particular attention.

These types of QFN have attracted particular attention in relation to manufacturing methods that enable radical improvement to productivity per lead frame surface area. Such methods include a manufacturing method in which a plurality of QFN chips is arrayed on the die pad of the lead frame, a sealing resin is used to collectively encapsulate die cavities, and thereafter cutting is used to divide into individual QFN structures.

In this type of QFN manufacturing method in which a plurality of semiconductor chips are collectively encapsulated, the region of the lead frame that is clamped by a molding die during resin encapsulation is only an outer part of the resin encapsulation region that completely covers the package pattern region. Therefore in the package pattern region, and in particular in the central portion, since the lead frame back surface cannot be pressed with a sufficient force onto the molding die, it is extremely difficult to prevent leakage of sealing resin onto the lead frame back surface and therefore problems arise due to the QFN terminals and the like being covered with resin.

As a result, a method of manufacture that can be effectively used as a method of QFN manufacture includes attachment of an adhesive tape to the back surface of the lead frame to thereby prevent resin leakage onto the lead frame back surface during resin encapsulating due to the encapsulating effect of using the adhesive force (masking) of the adhesive tape.

In other words, the attachment of a heat-resistant adhesive tape to the lead frame back surface after mounting of semiconductor chips on the lead frame and wire bonding presents substantial handling difficulties, therefore it is desirable that firstly the heat-resistant adhesive tape is attached to the back face of the lead frame, and after mounting of semiconductor chips and wire bonding, encapsulating is performed using a sealing resin, and then the heat-resistant adhesive tape is removed.

This type of method has been proposed as a method that executes a series of steps in which a heat-resistant adhesive tape having an adhesive agent layer of thickness 10 μm or less is used to prevent resin leakage while enabling wire bonding (For example refer to JP 2002-184801 A).

However in an encapsulating step using a sealing resin in a conventional manufacturing method for a semiconductor device, a gap may result from the accuracy of the lead frame to which the heat-resistant adhesive tape is applied, the design of the die, and in particular the lower die.

Therefore resin leakage may occur due to clamp failure of the molding portion and the outer peripheral portion between the lead frame and the heat-resistant adhesive tape due to the gap between the lead frame and the lower die.

### SUMMARY OF THE INVENTION

Present invention provides an adhesive tape for resin-encapsulating used in a method of manufacture of a resin-encapsulated semiconductor device comprising:

a base material layer and

an adhesive agent layer laminated on the base material layer,

a total film thickness of the base material layer and the adhesive agent layer of 25 to 40 μm.

Further, the present invention provides a method of manufacture of a resin-encapsulated semiconductor device comprising steps of:

attaching the adhesive tape of claim 1 at least one surface of a lead frame, mounting a semiconductor chip on the lead frame, encapsulating the semiconductor chip side with a sealing resin, and re-peeling the adhesive tape after encapsulating.

According to the adhesive tape for resin encapsulating according to the present invention, resin leakage can be efficiently prevented during the resin encapsulating operation.

Furthermore the method of manufacture of a resin-encapsulated semiconductor device according to the present invention enables efficient prevention of resin leakage during resin encapsulating operations, and improvement to productivity.

### BRIEF DESCRIPTION OF THE DRAWINGS

FIGS. 1a to 1f are schematic cross sectional view illustrating a step of a method of manufacturing a semiconductor device according to the present invention.

FIG. 2a is a plane view of a lead flame, and FIG. 2b is an enlarged view of the relevant part of a lead flame using a method of manufacturing a semiconductor device according to the present invention.

### DETAILED DESCRIPTION OF THE PREFERRED EMBODIMENTS

The adhesive tape for resin encapsulating according to the present invention includes at least a base material layer and an adhesive agent layer laminated thereon. The adhesive tape for resin-encapsulating is used when performing resin encapsulation during a semiconductor manufacturing process.

### Base Material Layer

There is no particular limitation on the base material layer and any material can be used as long as it is a material that can be used as a base material for an adhesive tape in this technical field.

In particular, the base material layer is suitably made of a material that is resistant to the heating that is normally used in semiconductor manufacturing processes, and in particular to the heating used in resin-encapsulating. For example, the material has heat resistant properties to a temperature of 170° C. or more, 200° C. or more, 250° C. or more, 300° C. or more. A sealing resin is generally subjected to a temperature of approximately 175° C., and therefore a material is preferred that does not cause conspicuous shrinkage of the base material layer or breakage of the base material under such a temperature condition.

From another aspect, it is preferred that the base material layer does not have a glass transition temperature (Tg) of 300° C. or less. In the manufacturing step of the semiconductor device, even when the adhesive tape is heated to more that the Tg of the base material layer, use of this type of base material layer enables prevention of warping of the lead frame and prevention of deformation and the like of the adhesive tape. In this manner, functions such as masking during resin encapsulating can be ensured and the success rate of wire bonding can be improved.

Tg is a value that is calculated with reference to ASTM D696 using a thermo-mechanical analysis apparatus (for example, TMA/SS600 manufactured by SIS Technology Inc.). A base material layer sample (for example, a thickness of 1 mm×a width of 4 mm) is heated under a load of 19.6 mN from room temperature at a rate of 10° C./min to thereby measure the thermal expansion amount with respect to the thickness direction with the thermal analysis apparatus. The relationship between the thermal expansion amount and temperature is plotted on a graph. Then tangent lines are drawn to the curve about the point predicted as the glass translation temperature. Tg is then calculated from the intersection point of these tangent lines. Therefore the fact that the base material layer does not have a glass transition temperature (Tg) of 300° C. or less means that a temperature predicted as a glass transition temperature cannot be identified, intersection of the tangent lines almost cannot be identified.

For the purpose of preventing warping of the lead frame resulting from shrinkage of the base material layer, the base material layer preferably has a heat shrinkage factor after heating for three hours at 180° C. of 0.40% or less.

The heat shrinkage factor as used herein means the ratio (%) of dimensional change taking the dimensions prior to heating (5 cm) as 100% when a 5 cm×5 cm base material layer is heated for three hours at 180° C. The heat shrinkage factor may be measured using a commercially available projector (Mitutoyo Corporation projector PJ-H3000F).

The base material layer can be made of resins such as polyethylene naphthalate (PEN), polyether sulfone (PES), polyether imide (PEI), polysulfone (PSF), polyphenylene sulfide (PPS), polyether etherketone (PEEK), polyarylate (PAR), aramido, polyimide, polyethylene terephthalate (PET), and the like; liquid crystal (LCP); metallic foil such as aluminum foil; glass cloth, and the like.

In particular, a most preferred material for the base material layer is a polyimide material having a coefficient of linear thermal expansion of about 1.0×10⁻⁵ to about 3.0×10⁻⁵/K, that has superior processing characteristics and handling characteristics, and that has excellent heat resistance and strength.

The base material layer may be a single layer or a laminated structure.

In view of the handling characteristics of the adhesive tape (for example, resistance to formation of folds or tears in the tape), the thickness of the base material layer is preferably at least 5 μm, and more preferably at least 10 μm. On the other hand, in view of the re-peelability of the adhesive tape, the thickness of the base material layer is preferably 35 μm or less, and more preferably 30 μm or less.

In another aspect, the lead frame to which the adhesive tape according to the present invention is attached as described hereafter is a metal material and generally has a coefficient of linear thermal expansion of the level of about 1.8 to about 1.9×10⁻⁵/K. Therefore when the coefficient of linear thermal expansion of the adhesive tape is considerably different to that of the lead frame, in the event that both are heated in an adhered configuration, a distortion will result due to the difference in the mutual coefficients of linear thermal expansion, and as a result will cause peeling and creases in the adhesive tape. For that reason, the coefficient of linear thermal expansion of the base material layer that configures the adhesive tape is suitably about 1.0 to about 3.0×10⁻⁵/K and approximates the coefficient of the lead frame material, and preferably about 1.5×10⁻⁵ to about 2.5×10⁻⁵/K.

The coefficient of linear thermal expansion is a value measured using TMA (thermo mechanical analysis) with reference to ASTM D696.

### Adhesive Agent Layer

The adhesive agent layer may be formed by an adhesive agent normally used in this technical field as long as the agent has heat resistant characteristics. The adhesive agent may be pressure sensitive, heat sensitive or photosensitive, but is suitably an adhesive agent that is cured by irradiation with energy rays. In this manner, after use, re-peeling from the adherend is facilitated.

The adhesive agent layer may be formed on both sides of the base material layer, but is suitably formed on only one side.

The adhesive agent configuring the adhesive agent layer for example includes acrylic adhesive agents, silicon adhesive agents, rubber adhesive agents, epoxy adhesive agents, and the like.

The acrylic adhesive agents may be made of an acrylic copolymer which is copolymerized monomer including alkyl (meth) acrylic acids or alkyl (meth) acrylic acid(s) with other monomer(s). In this specification, the alkyl (meth) acrylic acid means an alkyl acrylic acid and/or alkyl methacrylic acid.

Examples of the alkyl (meth) acrylic acid include methyl (meth) acrylic acid, ethyl (meth) acrylic acid, propyl (meth) acrylic acid, butyl (meth) acrylic acid, isoamyl (meth) acrylic acid, n-hexyl (meth) acrylic acid, 2-ethylhexyl (meth) acrylic acid, isooctyl (meth) acrylic acid, isononyl (meth) acrylic acid, decyl (meth) acrylic acid, dodecyl (meth) acrylic acid, and the like. Among these, a copolymer of acrylic acid and 2-ethylhexyl (meth) acrylic acid, and a copolymer of methyl/ethyl (meth) acrylic acid, acrylic acid and 2-ethylhexyl (meth) acrylic acid are preferable.

The adhesive agent layer, and in particular an adhesive agent layer that includes an acrylic adhesive agent, may include a cross linking agent.

The cross linking agent for example includes an isocyanate cross linking agent, an epoxy cross linking agent, an aziridine compound, a chelating cross linking agent, and the like.

The content of the cross linking agent is not particularly limited, however is suitably about 0.1 to about 15 parts, and more preferably about 0.5 to about 10 parts per weight for 100 parts per weight of the acrylic polymer. The use of the cross linking agent in this range enables setting of the viscoelasticity of the adhesive agent layer to a suitable level, and enables maintenance of a suitable adhesive force in the adhesive agent layer relative to the conductive pattern or the sealing resin. Therefore even when re-peeling the adhesive tape, the sealing resin is not removed or damaged, and a part of the adhesive agent layer does not become attached to the conductive pattern or the sealing resin. Furthermore excessive curing of the adhesive agent layer can be suppressed.

Various types of additive agents normally used in this technical field may be added to the adhesive agent layer, the additive agent includes a plasticizer, a pigment, a dye, an anti-oxidant, an antistatic agent, a filling agent added to improve the physical properties of the adhesive agent layer such as the modulus of elasticity, or the like.

From the point of view of sufficient adhesive strength with the lead frame, the thickness of the adhesive agent layer is 2 μm or more, more preferably 3 μm or more, and still more preferably 4 μm or more. On the other hand, from the point of view of sufficient wire bonding, the thickness is preferably 35 μm or less, and more preferably 30 μm or less.

### Manufacture of Adhesive Tape

The adhesive agent layer may be formed by preparing the adhesive agent component and then coating and drying that component onto the base material layer. The method of coating the adhesive agent component may adopt various methods including bar coating, air-knife coating, gravure coating, gravure reverse coating, reverse roll coating, rip coating, die coating, dip coating, offset printing, flexo printing, screen printing, and the like. Furthermore a method can be used in which the adhesive agent layer separately formed on a release liner, and then adhered to the base material film.

### Adhesive Tape

The adhesive tape according to the present invention suitably has a total film thickness of the base material layer and the adhesive agent layer of about 25 to about 40 μm, and more preferably about 25 to about 35 μm.

A total film thickness in this range, as described below, prevents creases when adhering to the lead frame, and for example effectively prevents resin leakage from between dies through combination with the clamp pressure when the lead frame with the adhesive tape attached thereto is sandwiched with the die.

The adhesive tape according to the present invention suitably has an adhesive force at a peel angle of 180° of the adhesive tape to the lead frame of at least 0.01 N/19 mm width, preferably at least 0.05 N/19 mm width, more preferably at least 0.10 N/19 mm width, and still more preferably at least 0.15 N/19 mm width, for the purpose of a sufficient adhesive force (not producing tape peeling during processing) on the lead frame, and suitably has an adhesive force of less than or equal to 10.0 N/19 mm width, preferably less than or equal to 6.0 N/19 mm width, more preferably less than or equal to 5.0 N/19 mm width, and still more preferably less than or equal to 4.0 N/19 mm width in order to prevent deformation of the die pad portion and the like, or adhesive residue upon tape removal due to failure of tape adhesion.

The adhesive tape according to the present invention suitably has an adhesive force at a peel angle of 180° of the adhesive tape to the sealing resin of less than or equal to 10.0 N/19 mm width, preferably less than or equal to 6.0 N/19 mm width, and more preferably less than or equal to 5.0 N/19 mm width.

The adhesive force is a value measured by removal from the lead frame under conditions of measurement temperature 23±2° C., peel angle 180°, and peel speed 300 mm/min (based on JIS Z0237). This measurement may be performed using a commercially available measurement apparatus (Autograph AG-X or the like, manufactured by Shimadzu Corporation).

On the other hand, the adhesive tape is firstly adhered to the lead frame and re-peeled at an arbitrary stage from the lead frame. However when a strong adhesive force is present, not only is peeling difficult, but sometimes removal or damage to the molded resin is caused by the stress resulting from peeling. Therefore a strong peeling force that is greater than or equal to the adhesive force that suppresses extraction (protrusion or strays) of the sealing resin is not preferred. For example, in the manufacturing step of a semiconductor device, an adhesive force at 25° C. based on JIS C2107 of about 5 to about 10000 N/m is suitable. Furthermore an adhesive force on the lead frame after heating for one hour at 200° C. is suitably at least about 0.05 N/19 mm width, preferably at least about 0.1 N/19 mm width, and suitably less than or equal to 6 N/19 mm width and preferably less than or equal to 4 N/19 mm width.

In particular, an adhesive force is suitably about 0.05 to about 6.0 N/19 mm width, preferably about 0.1 to about 4.0 N/19 mm width, and more preferably about 0.1 to about 2.0 N/19 mm width.

The adhesive tape according to the present invention is preferably provided with a release sheet. The release sheet is a sheet formed by contact with the adhesive agent layer in order to protect the adhesive agent layer. The adhesive tape preferably has a specific peel strength corresponding for example to the type of the adhesive agent included in the adhesive agent layer. The peel strength can be suitably adjusted by the angle when re-peeling the adhesive tape. For example, a tape that satisfies at least one of the peel strengths at a peel angle as shown below is preferred. As used herein, peel strength is a value that is measured by peeling from the adhesive tape of the present invention under conditions of measurement temperature 23±2° C., peel angle 75 to 195°, and preferably 90 to 180°, and peel speed 300 mm/min (based on a TMA0001 method).

The peel strength at a peel angle of 90±15° of the release sheet is suitably less than or equal to 1.5 N/50 mm width, preferably less than or equal to 1.0 N/50 mm width, more preferably less than or equal to 0.5 N/50 mm width, still more preferably less than or equal to 0.3 N/50 mm width, and further still more preferably less than or equal to 0.2 N/50 mm width.

The peel strength at a peel angle of 120±15° of the release sheet is suitably less than or equal to 1.2 N/50 mm width, preferably less than or equal to 1.0 N/50 mm width, more preferably less than or equal to 0.8 N/50 mm width, still more preferably less than or equal to 0.6 N/50 mm width, and further still more preferably less than or equal to 0.3 N/50 mm width.

The peel strength at a peel angle of 150±15° of the release sheet is suitably less than or equal to 1.0 N/50 mm width, preferably less than or equal to 0.8 N/50 mm width, more preferably less than or equal to 0.6 N/50 mm width, still more preferably less than or equal to 0.5 N/50 mm width, further still more preferably less than or equal to 0.3 N/50 mm width, and furthermore still preferably less than or equal to 0.2 N/50 mm width.

The peel strength at a peel angle of 180+0° to 180−15° of the release sheet is suitably less than or equal to 1.0 N/50 mm width, preferably less than or equal to 0.8 N/50 mm width, more preferably less than or equal to 0.6 N/50 mm width, still more preferably less than or equal to 0.5 N/50 mm width, further still more preferably less than or equal to 0.3 N/50 mm width, and furthermore still more preferably less than or equal to 0.2 N/50 mm width.

When the peel strength is in the above range, even when using a general purpose tape application apparatus, an excessive peel strength is not required to release the release sheet, creases in the adhesive sheet or deviation in the attachment position do not occur, and a residual stress on the adhesive tape can be prevented. In this manner, resin leakage of sealing resin, and warping of the lead frame can be suppressed.

The release sheet can be made of a material as a base film that is generally used in this technical field, for example, polyvinylchloride; polyvinylidene chloride; polyester such as polyethylene terephthalate; polyimide; poly etheretherketone; polyolefins such as low-density polyethylene, liner polyethylene, medium-density polyethylene, high-density polyethylene, ultralow density polyethylene, random copolymer polypropylene, block copolymer polypropylene, homo-polypropylene, polybutene, polymethylpentene; polyurethane; ethylene-vinyl acetate copolymer; ionomer resin; ethylene-(meth)acrylic acid copolymer; ethylene-(meth)acrylic ester (random or alternating) copolymer; ethylene-butene copolymer; ethylene-hexene copolymer; fluorine resin; cellulose resin; and cross-linked material thereof. These can be used alone or as mixture of two or more. The base film can be formed single layer or multilayer of two or more layers.

The release sheet is suitably a sheet that is release-processed to not substantially adhere to the adhesive agent layer on at least a face that touches the adhesive agent layer of the base film. The release-processing may use a material or a method known in this technical field. For example, it may include processing using silicon resin, release processing using a fluorine resin, or the like. More specifically, light release grade or medium release grade of the Cerapeel series (Toray Advanced Film Co., Ltd.) may be used.

### Method of Manufacture of Resin Encapsulated Semiconductor Device, and Method of Preventing Resin Leakage

According to the method of manufacture of a resin-encapsulated semiconductor device, the adhesive tape of the present invention is used when manufacturing a semiconductor device, and in particular used when performing resin encapsulating. In other words, it is used to attach to at least one face of a lead frame, for example, the back surface (the surface opposite the surface on which the semiconductor chip is mounted, same hereafter) when resin-encapsulating a semiconductor chip that is mounted on the lead frame surface, and then re-peeling after encapsulation.

The method for manufacturing a semiconductor device includes a step of:
attaching the adhesive tape according to the present invention to at least one surface of the lead frame, for example the back surface,
mounting the semiconductor chip on the die pad surface,
encapsulating the semiconductor chip side with a sealing resin, and re-peeling the adhesive tape after encapsulating.

The method may include the further step of, during the attachment to the removal of the adhesive tape,
plasma-processing,
cutting the sealing resin after resin encapsulating,
irradiating the adhesive tape through the lead frame from the lead frame side; and
connecting after the mounting of the semiconductor chip on the die pad.

The tape is mainly used for preventing resin leakage in such method. The adhesive tape may be attached to any region on the top and back surfaces other than the region which is encapsulated by resin.

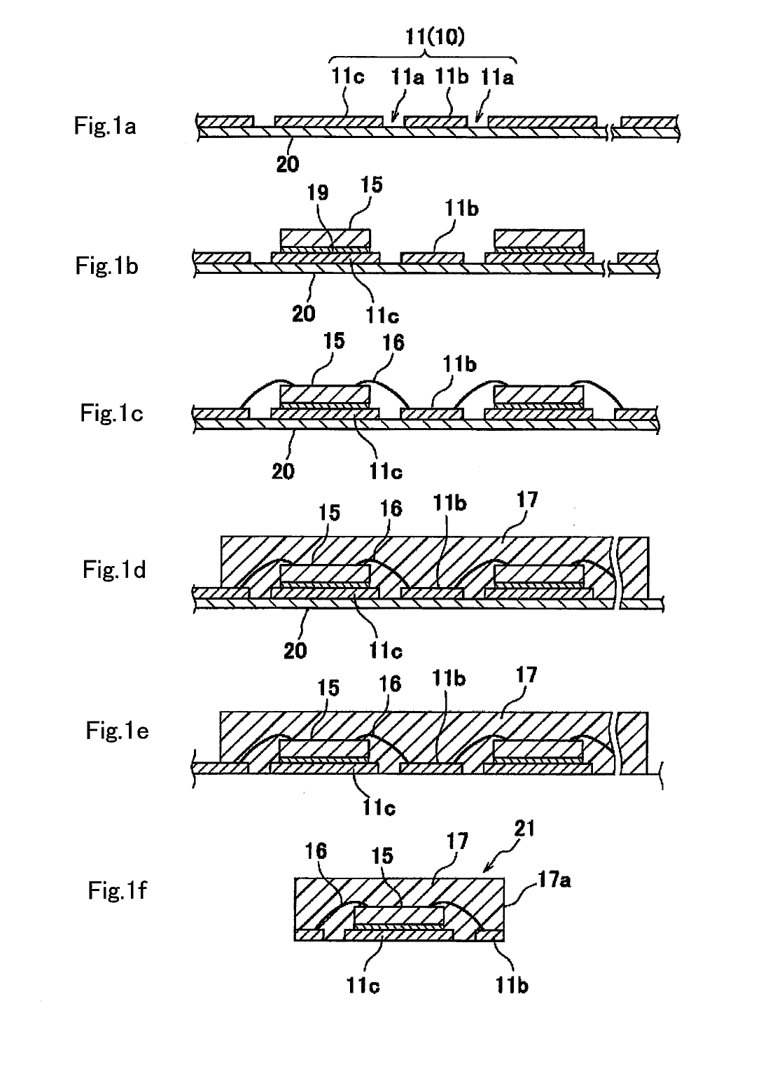

More specifically, firstly as shown in FIG. 1(a), an adhesive tape 20 according to the present invention is attached to one surface of the lead frame 11, that is to say, the back surface.

The lead frame 11 is normally formed from a metal plate of a material such as a Cu-based material (Cu—Fe—P or the like), an Fe-based material (Fe—Ni or the like). Furthermore the QFN terminal pattern may be engraved. In particular, it is preferred that the electrical connection portions in the lead frame (the connection portions with the semiconductor chip as described below) are covered (plated) with a metal such as silver, nickel, palladium, gold, or the like. The thickness of the lead frame 11 is normally about 100 to about 300 μm.

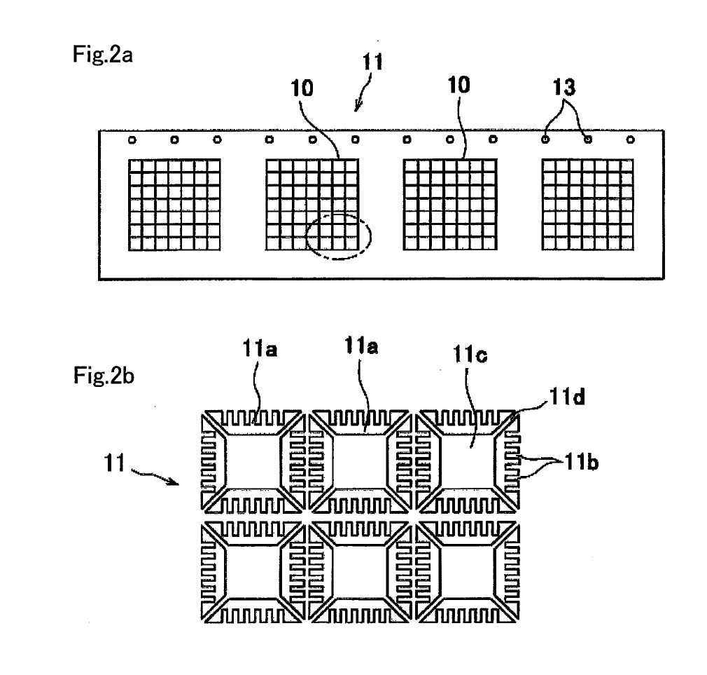

The lead frame 11 preferably arrays a plurality of predetermined disposition patterns (for example, individual QFN disposition patterns) to facilitate cutting in the subsequent cutting step. More specifically, as shown in FIGS. 2a and 2b, a configuration is more preferred in which a package pattern region 10 is arrayed on the lead frame 11 in a matrix configuration termed a matrix QFN, MAP-QFN, or the like.

The lead frame 11 normally includes a die pad 11c and a lead terminal 11b. Although these components may be provided separately, as shown in FIG. 2b, it is preferred that they are integrated by a plurality of lead terminals 11b defined by a plurality of adjacent openings 11a, a die pad 11c arrayed in the center of the openings 11a, and as required, a die bar 11d supporting the die pad 11c on the four corners of the openings 11a. The die pad 11c, the lead terminal 11b, and the like may be formed for the purpose of another function such as releasing heat or the like.

The attachment of the adhesive tape 20 to the lead frame 11 is suitably performed at least in the package pattern region 10 in the lead frame 11; in the region outside the package pattern region 10 of the lead frame 11, that is to say, the region including the entire periphery outside the resin encapsulation region that is encapsulated with resin; or in the package pattern region 10 and the region including the entire periphery outside the package pattern region 10.

When the adhesive tape according to the present invention may be attached to the region including the entire periphery outside the resin encapsulation region, attachment may be performed not only to the back surface of the lead frame but also to the front surface. When attachment is performed to the region including the package pattern region 10 and the entire periphery outside of the package pattern region 10, attachment only to the back surface of the lead frame is preferred.

Since the lead frame 11 may include guide pin holes (for example refer to reference numeral 13 in FIG. 2a) in proximity to the edge for the purpose of positioning during resin encapsulating, it is preferred that the adhesive tape is attached to a region other than the holes. Furthermore a plurality of package pattern regions 10 is disposed in a longitudinal direction of the lead frame 11, and therefore it is preferred that the adhesive tape 20 is attached continuously across the plurality of regions.

Next as shown in FIG. 1(b), the semiconductor chip 15 is mounted on the top surface of the lead frame 11 (the surface on which the adhesive tape 20 is not attached).

Normally, as described above, since the lead frame 11 includes a fixed area termed a die pad 11c for fixing the semiconductor chip 15, the semiconductor chip 15 is mounted on the die pad 11c.

The mounting of the semiconductor chip 15 on the die pad 11c for example may be performed using various methods including a conductive paste 19, an adhesive tape, an adhesive (for example, a heat-cured adhesive agent), or the like. When mounting using a conductive paste, an adhesive agent, or the like, normally heating and curing is performed for about 30 to about 90 minutes at a temperature of about 150 to about 200° C.

To create high flexibility by curing the adhesive agent layer in the adhesive tape, irradiation may be performed on the resulting lead frame 11 from the lead frame 11 side.

There is no particular limitation on the type of radiation, and suitable adjustment is possible in relation to the type of adhesive agent contained in the adhesive agent layer. For example, the radiation includes ultraviolet radiation, electron beams, or the like, with ultraviolet radiation being preferred. There is no particular limitation on the wavelength of the ultraviolet beams, and a wavelength generally used in photo-induced polymerization may be suitably selected. For example, a wavelength of ultraviolet light of about 250 to about 400 nm is suitable.

The method of irradiating ultraviolet radiation may use a conventional known ultraviolet radiation generating apparatus. More specifically, an ultraviolet radiation apparatus adopting a discharge lamp configuration (arc-lamp), a flash configuration, a laser configuration, or the like may be adopted. Of these configurations, a discharge lamp configuration is preferred due to productivity in industrial applications. Furthermore from the point of view of radiation efficiency of the irradiation, use of a high-pressure mercury lamp, or a metal halide lamp is preferred.

The irradiation amount is adapted to improve the efficiency of the polymerization initiator contained in the adhesive agent layer. More specifically, the irradiation may be about 10 to about 1000 mJ/cm², and about 50 to about 600 mJ/cm² is preferred. This is for the purpose of realizing suitable curing of the adhesive agent layer.

The irradiation may be performed at any stage as long as it is after the attachment of the adhesive tape 20 to the lead frame 11 and before wire bonding as described below. For example, it is preferred that irradiation is performed during the attachment of the adhesive tape through the resin sealing. When performed before the attachment of the adhesive tape 20 to the lead frame 11, the adhesive force is reduced by the curing of the adhesive agent layer and adhesion becomes difficult. Furthermore this is also due to the fact that there is a tendency for sealing resin to leak as described below.

Next, as shown in FIG. 1c, an electrode pad (not shown) on the top surface of the semiconductor chip 15 and the lead frame 11 may be wire bonded (connected).

Wire bonding is performed by use of a bonding wire 16, for example, gold wire, or aluminum wire, or the like. Normally, it is performed by heating to about 150 to about 250° C., and combining vibrational energy from ultrasonic waves and pressure energy from application of pressure. At this time, vacuum suction of the adhesive tape surface attached to the lead frame enables accurate fixation to the heat block.

When mounting the semiconductor chip 15 face-down, a suitable reflow step may be included.

Next, a sealing resin 17 is injected into a mold, that is, the lead frame 11 is sandwiched by the upper and lower dies (not shown), and the sealing resin 17 (for example, an epoxy resin, or the like) is injected to thereby encapsulate the semiconductor chip 15. The resin for sealing preferably has a viscosity of about 0.8 to 2.0 Pa·s, and more preferably of about 1.0 to 2.0 Pa·s. The viscosity of the resin can be measure by a commercially available viscometer (for example, rheometer, capillary rheometer and the like). The injecting temperature of the resin is preferably about 160 to about 190° C. The injecting pressure of the resin is preferably about 150 to about 220 kN. This encapsulating operation includes both single-sided encapsulation and double-sided encapsulation.

When performing double-sided encapsulation, as described above, an adhesive tape is suitably attached to the top surface and/or the back surface of the lead frame in a region including the entire periphery outside the resin encapsulation region on the lead frame.

When attaching the adhesive tape to a single surface of the region including the package pattern region 10 and the entire periphery outside the package pattern region 10, single-sided encapsulation is preferred. This operation is preferred since the adhesive tape according to the present invention is particular adapted for use in relation to this type of encapsulation operation.

The encapsulation of the semiconductor chip is performed to protect the semiconductor chip 15 and the bonding wire 16 mounted on the lead frame 11. For example, a method such as in-die molding (i.e., injection molding) using an epoxy resin or the like may be typically used. In this case, it is preferred to encapsulate a plurality of semiconductor chips at the same time using a die configured from an upper die and a lower die that has a plurality of cavities. In such method, sealing preferably is performed by the injection molding at a clamping pressure of the mold of 3 to 7 kN. Normally, the heating temperature during resin encapsulation is about 170 to about 180° C., and after curing for several minutes at that temperature, post molding curing is executed for several hours.

Thereafter as shown in FIG. 1d, the lead frame 11 including the sealing resin 17 is removed from the die.

As shown in FIG. 1e, the adhesive tape 20 attached to the back surface of the lead frame 11 is re-peeled.

The removal of the adhesive tape 20 after encapsulation is preferably performed prior to post molding curing as described above.

Thereafter as shown in FIG. 1f, the lead frame 11 including the sealing resin 17 is divided into semiconductor chips 15 to thereby obtain a semiconductor device 21.

The division of each semiconductor chip 15 can be executed using a rotary cutting blade or the like such as a dicer or the like.

The adhesive tape according to the present invention may be attached to one surface of the lead frame, preferably the back surface, during resin encapsulation of the semiconductor chip. In the steps shown in FIG. 1a to 1c, the adhesive tape may be attached after mounting of the semiconductor chip, or the adhesive tape may be attached after wire bonding of the semiconductor chip. Of these operations, it is preferred that the sequence shown in FIG. 1a to FIG. 1c as described above is executed. Furthermore it is not necessary to execute wire bonding depending of the structure of the semiconductor chip.

The resin-encapsulation adhesive tape according to the present invention and a method of manufacturing a resin-encapsulated semiconductor device using the tape will be described in detail below.

In the absence of an express indication to the contrary in the embodiments and comparative examples, parts and % refers to parts by weight.

### Example 1

A 25 μm polyimide film (Kapton 100H, coefficient of linear expansion 2.7×10⁻⁵/K, Tg: 402° C., Du Pont-Toray Co., Ltd.) was used as a base material layer. 2.5 parts of a platinum catalyst was added to 100 parts of a silicon-base adhesive agent (SD4584 manufactured by Dow Corning Toray Co., Ltd.), and coated and dried on one surface of the base material layer to thereby obtain a heat-resistant adhesive tape having an adhesive agent layer of thickness about 6 μm (total film thickness about 31 μm).

### Example 2

A 12.5 μm polyimide film (Kapton 50H, coefficient of linear expansion 2.7×10⁻⁵/K, Tg: 402° C., Du Pont-Toray Co., Ltd.) was used as a base material layer. The silicon-base adhesive agent was used, and obtained a heat-resistant adhesive tape having an adhesive agent layer of thickness about 8 μm (total film thickness about 30.5 μm), in the same manner as Example 1.

### Example 3

A 25 μm polyethylene terephthalate film (Lumirror S10, coefficient of linear expansion 1.2×10⁻⁵/K, Tg: 67° C., Toray Industries Inc.) was used as a base material layer. To 100 parts of polymer made of butyl acrylate-ethyl acrylate-acrylic acid (butyl acrylate: ethyl acrylate: acrylic acid=70 parts: 30 parts: 40 parts) were added 3 parts of isocyanate cross linking agent (trade name “Coronate L,” made by Nippon Polyurethane Industry), 2 parts of epoxy cross linking agent (trade name “tetrad C,” made by Mitsubishi gas chemical company, Inc.) and toluene, and mixed and stirred to prepare an adhesive solution.

The obtained adhesive solution was coated and dried on one surface of the base material layer to thereby obtain a heat-resistant adhesive tape having an adhesive agent layer of thickness about 10 μm (total film thickness about 35 μm).

### Comparative Example 1

A heat-resistant adhesive tape was manufactured in the same manner as the Example 1 with the exception that the thickness of the adhesive agent layer of about 35 μm (total film thickness about 60 μm).

### Comparative Example 2

A 12.5 μm polyimide film (Kapton 50H, coefficient of linear expansion 2.7×10⁻⁵/K, Tg: 402° C., Du Pont-Toray Co., Ltd.) was used as a base material layer. The acrylic adhesive agent described in Example 3 was used, and obtained a heat-resistant adhesive tape having an adhesive agent layer of thickness about 6 μm (total film thickness about 18.5 μm).

### Functional Evaluation

The adhesive tape manufactured according to the Example and Comparative Examples was attached with an uniform operation to form a firm attachment at ambient temperature using a tape laminating apparatus PL-55TRM (Nitto Denko Corporation) to an outer pad of the back surface of a copper lead frame configuring a 16-pin QFN in a 4×4 array with terminals which were plated with a silver. Semiconductor chips were mounted on the die pad of this lead frame and wire bonding was executed using gold wire.

Next, molding was executed using an epoxy sealing resin (HC-300, Nitto Denko Corporation; resin viscosity: 0.8 to 2.0 Pa·S) with a molding machine (Model Y-series manufactured by Towa Japan) at 175° C. using a preheat of 40 seconds, an injection time of 11.5 seconds, injection pressure of 150 to 220 kN and a curing time of 120 seconds. At this time, the clamping pressure of the molds was 3 to 7 kN.

Then the adhesive tape attached to the back surface of the lead frame was re-peeled.

After executing post molding curing for about 3 hours at 175° C. to thereby sufficiently cure the resin, cutting was executed using a dicer to thereby obtain individual QFN semiconductor devices. After manufacturing the QFN semiconductor devices in this manner, a visual inspection was performed in relation to resin leakage.

As a result, no resin leakage was observed in Examples 1 to 3. On the other hand, in Comparative Example 1, resin leakage onto the terminal of at least 60% was confirmed. In Comparative Example 2, resin leakage onto the terminal of at least 80% was confirmed.

The adhesive tape according to Examples 1 to 3 was respectively used to prepare an adhesive tape attached to a PET separator of thickness 50 μm (MRS-50S manufactured by Mitsubishi Polyester Film Co., Ltd.) and a PET separator of thickness 38 μm (#38 Cerapeel, Toray Advanced Film Co., Ltd).

The peel force with the separator was measured at a 90°, 120°, 150° or 180° peel angle of the adhesive tape. The evaluation results of the separator peel force are shown in Table 1 and Table 2.

TABLE 1

| | PET Separator (Thickness: 50 μm) | | | |
|---|---|---|---|---|
| | Angle | | | |
| | 90° | 120° | | |
| | Peel Force | Peel Force | 150° Peel Force | 180° Peel Force |
| EX. 1 | 0.15 | 0.11 | 0.06 | 0.06 |
| EX. 2 | 0.19 | 0.15 | 0.09 | 0.06 |
| EX. 3 | 0.11 | 0.08 | 0.05 | 0.04 |

TABLE 2

| | PET Separator (Thickness: 38 μm) | | | |
|---|---|---|---|---|
| | Angle | | | |
| | 90° | 120° | | |
| | Peel Force | Peel Force | 150° Peel Force | 180° Peel Force |
| EX. 1 | 0.10 | 0.06 | 0.05 | 0.04 |
| EX. 2 | 0.11 | 0.08 | 0.06 | 0.04 |
| EX. 3 | 0.08 | 0.05 | 0.04 | 0.03 |

As shown in Tables 1 and 2, any of the adhesive taps in the Examples displayed a result of peel force of less than 0.3 N/50 mm.

Furthermore when using these adhesive tapes, positional deviation of the attachment of the adhesive tape, warping of the lead frame, or leakage of the sealing resin were not observed.

This application claims priority to Japanese Patent Application No. 2009-258633. The entire disclosure of Japanese Patent Application No. 2009-258633 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. An adhesive tape for resin-encapsulating used in a method of manufacture of a resin-encapsulated semiconductor device comprising:
a base material layer and
an adhesive agent layer laminated on the base material layer,
a total film thickness of the base material layer and the adhesive agent layer of 25 to 40 μm.

2. The adhesive tape of claim 1, wherein
the adhesive agent layer has a thickness of 2 to 25 μm.

3. The adhesive tape of claim 1, wherein
the adhesive tape is used for attaching to at least one face of a lead frame at resin-encapsulating a semiconductor chip that is mounted on the lead frame surface, and then re-peeling after encapsulation.

4. The adhesive tape of claim 1, wherein
the adhesive agent layer is laminated only on one face of the base material layer.

5. The adhesive tape of claim 1, wherein
the adhesive tape has a release sheet which is contacted with the adhesive agent layer, and the release sheet has
a peel strength at a peel angle of 90±15° of less than or equal to 1.5 N/50 mm width,
a peel strength at a peel angle of 120±15° of less than or equal to 1.2 N/50 mm width,
a peel strength at a peel angle of 150±15° of less than or equal to 1.0 N/50 mm width, or
a peel strength at a peel angle of 180+0° to 180−15° of less than or equal to 1.0 N/50 mm width.

6. A method of manufacture of a resin-encapsulated semiconductor device comprising steps of:
attaching the adhesive tape of claim 1 at least one surface of a lead frame,
mounting a semiconductor chip on the lead frame,
encapsulating the semiconductor chip side with a sealing resin, and
re-peeling the adhesive tape after encapsulating.

7. The method of manufacture of a resin-encapsulated semiconductor device of claim 6, wherein sealing is performed using with a sealing resin having a viscosity of 0.8 to 2.0 Pa·s.

8. The method of manufacture of a resin-encapsulated semiconductor device of claim 6, wherein sealing is performed by the injection molding at a injecting temperature of 160 to 190° C.

9. The method of manufacture of a resin-encapsulated semiconductor device of claim 6, wherein sealing is performed by the injection molding at a injecting pressure of 150 to 220 kN.

10. The method of manufacture of a resin-encapsulated semiconductor device of claim 6, wherein sealing is performed by the injection molding at a clamping pressure of a mold of 3 to 7 kN.

11. The method of manufacture of a resin-encapsulated semiconductor device of claim 6, further comprising irradiating the adhesive tape through the lead frame from the lead frame side during the attachment of the adhesive tape through the resin sealing.
